(19) United States
(12) Patent Application Publication
(10) Pub. No.: US 2022/0158118 A1
(43) Pub. Date: May 19, 2022

(54) LIGHT EMITTING DEVICE, DISPLAY DEVICE AND MANUFACTURING METHOD OF LIGHT EMITTING DEVICE

(71) Applicant: BOE Technology Group Co., Ltd., Beijing (CN)

(72) Inventor: Jingwen FENG, Beijing (CN)

(21) Appl. No.: 17/360,421

(22) Filed: Jun. 28, 2021

(30) Foreign Application Priority Data
Nov. 17, 2020 (CN) 202011285368.9

(51) Int. Cl. H01L 51/52; H01L 51/56; H01L 51/50

(52) U.S. Cl. CPC H01L 51/5206; H01L 51/5221; H01L 51/502; H01L 51/56

(57) ABSTRACT

Disclosed are a light emitting device, a display device and a manufacturing method of the light emitting device. The light emitting device includes a base substrate, a first electrode located on one side of the base substrate, a light emitting layer located on a side, away from the base substrate, of the first electrode, and a second electrode located on a side, away from the first electrode, of the light emitting layer, wherein a least one light adjusting layer is arranged between the first electrode and the second electrode, the light adjusting layer generates carriers when irradiated by light emitted by the light emitting layer, and the carriers enter the light emitting layer under the action of an electric field generated by the first electrode and the second electrode.

This application claims priority to Chinese Patent Application No. 202011285368.9, filed on Nov. 17, 2020, which is hereby incorporated by reference in its entirety.

### FIELD

The present application relates to the field of display, in particular to a light emitting device, a display device and a manufacturing method of the light emitting device.

### BACKGROUND

With the development of quantum dot materials, the continuous optimization of device structures, the continuous in-depth research on effective charge transport and the like, quantum dot light emitting diodes (QLEDs) will exceed photoluminescence quantum dot brightness enhancement films and quantum dot color filters in terms of display, and are expected to become the mainstream display technology of the next generation.

In the QLED device, there are three main factors influencing the external quantum efficiency of the device, including a photoluminescence quantum yield (PLQY) of a quantum dot material, the carrier injection balance in the device and a light extraction rate. As the QLED device adopts a “sandwich-type” multi-layer stacked structure, about 75% of light emitted by the QLED device is dissipated by non-radiation coupling modes such as a waveguide mode caused by total reflection between layers in the device, a substrate mode between ITO glass and air and a surface plasma effect generated between metal electrodes, and finally, only about 25% of light can be emitted from the device.

### SUMMARY

The present disclosure provides a light emitting device, a display device and a manufacturing method of the light emitting device.

An embodiment of the present disclosure provides a light emitting device. The light emitting device includes a base substrate, a first electrode located on one side of the base substrate, a light emitting layer located on a side, away from the base substrate, of the first electrode, and a second electrode located on a side, away from the first electrode, of the light emitting layer, where at least one light adjusting layer is arranged between the first electrode and the second electrode, the at least one light adjusting layer generates carriers when the at least one light adjusting layer is irradiated by light emitted by the light emitting layer, and the carriers enter the light emitting layer under an action of an electric field generated by the first electrode and the second electrode.

In some embodiments, the light emitting layer includes a plurality of light emitting parts emitting different light wave bands, the at least one light adjusting layer includes adjusting parts corresponding to different light emitting parts, and band gaps of different adjusting parts are different.

In some embodiments, a band gap of an adjusting part is in negative correlation with the wavelength of light emitted by a corresponding light emitting part.

In some embodiments, the light emitting layer includes a first light emitting part emitting a first light wave band, a second light emitting part emitting a second light wave band, and a third light emitting part emitting a third light wave band, where a wavelength range of the first light wave band is greater than a wavelength range of the second light wave band, and the wavelength range of the second light wave band is greater than a wavelength range of the third light wavelength band; and a light adjusting layer includes a first adjusting part corresponding to the first light emitting part, a second adjusting part corresponding to the second light emitting part and a third adjusting part corresponding to the third light emitting part; where a band gap of the first adjusting part is larger than 0 eV and smaller than or equal to 1.97 eV, a band gap of the second adjusting part is larger than 1.97 eV and smaller than or equal to 2.3 eV, and a band gap of the third adjusting part is larger than 2.3 eV and smaller than or equal to 2.8 eV.

In some embodiments, the light emitted by the light emitting layer is emitted through the first electrode, and a light adjusting layer is located between the second electrode and the light emitting layer.

In some embodiments, the first electrode is an anode and the second electrode is a cathode; and the light adjusting layer generates electrons when the light adjusting layer is irradiated by the light emitted by the light emitting layer, and the electrons enter the light emitting layer under the action of the electric field generated by the first electrode and the second electrode.

In some embodiments, the first electrode is a cathode and the second electrode is an anode; and the light adjusting layer generates holes when the light adjusting layer is irradiated by the light emitted by the light emitting layer, and the holes enter the light emitting layer under the action of the electric field generated by the first electrode and the second electrode.

In some embodiments, the light emitted by the light emitting layer is emitted through the second electrode, and a light adjusting layer is located between the first electrode and the light emitting layer.

In some embodiments, the first electrode is an anode and the second electrode is a cathode; and the light adjusting layer generates holes when the light adjusting layer is irradiated by the light emitted by the light emitting layer, and the holes enter the light emitting layer under the action of the electric field generated by the first electrode and the second electrode.

In some embodiments, the first electrode is a cathode and the second electrode is an anode; and the light adjusting layer generates electrons when the light adjusting layer is irradiated by the light emitted by the light emitting layer, and the electrons enter the light emitting layer under the action of the electric field generated by the first electrode and the second electrode.

In some embodiments, the at least one light adjusting layer is located on one side of the light emitting layer and is adjacent to the light emitting layer.

In some embodiments, the light emitting device further includes: a first functional layer between the first electrode and the light emitting layer, and a second functional layer between the light emitting layer and the second electrode; and the at least one light adjusting layer is located between the first functional layer and the light emitting layer, or the at least one light adjusting layer is located between the second functional layer and the light emitting layer.

In some embodiments, the light emitting device further includes: a first functional layer between the first electrode and the light emitting layer, and a second functional layer between the light emitting layer and the second electrode; and the at least one light adjusting layer is located between the first functional layer and the first electrode, or the at least one light adjusting layer is located between the second functional layer and the second electrode.

In some embodiments, a material of the at least one light adjusting layer is a visible light photocatalytic material.

In some embodiments, the material of the at least one light adjusting layer includes one or a combination of:

bismuth vanadate;

bismuth phosphate;

bismuth iodate;

bismuth titanate;

a heavy metal ion doped derivative of bismuth vanadate;

a heavy metal ion doped derivative of bismuth phosphate;

a heavy metal ion doped derivative of bismuth iodate;

a heavy metal ion doped derivative of bismuth titanate;

borate;

a precious metal supported derivative of borate;

titanium dioxide; and

an ion-doped derivative of titanium dioxide.

In some embodiments, a thickness of a light adjusting layer ranges from 1 nm to 100 nm.

In some embodiments, the light emitting layer is a quantum dot light emitting layer; or the light emitting layer is an organic light emitting layer.

An embodiment of the present disclosure further provides a display device which includes the light emitting device provided by the embodiments of the present disclosure.

An embodiment of the present disclosure further provides a manufacturing method of the light emitting device provided by the embodiment of the present disclosure, including:

forming a first electrode on one side of a base substrate;

forming a light emitting layer on a side, away from the base substrate, of the first electrode; and

forming a second electrode on a side, away from the first electrode, of the light emitting layer;

where after forming the first electrode on one side of the base substrate and before forming the second electrode on the side, away from the first electrode, of the light emitting layer, the manufacturing method further includes:

forming at least one light adjusting layer between the first electrode and the second electrode.

In some embodiments, forming at least one light adjusting layer between the first electrode and the second electrode includes:

forming a bismuth tungstate photocatalyst; and

forming the bismuth tungstate photocatalyst between the first electrode and the second electrode through a coating, evaporation, sputtering or printing process.

In some embodiments, forming the bismuth tungstate photocatalyst includes:

weighing Bi(NO₃)₃.5H₂O and Na₂WO₄.2H₂O according to a molar ratio being as a first preset ratio;

dissolving Na₂WO₄.2H₂O into distilled water, and carrying out magnetic stirring for a first time duration to form a first solution;

dissolving Bi(NO₃)₃.5H₂O into an HNO₃ solution with a first concentration, and carrying out magnetic stirring for a second time duration to form a second solution;

while stirring, dropwise adding the first solution into the second solution to form a mixed solution;

adjusting a pH value of the mixed solution by using an HCl solution with a first concentration and a NaOH solution with a second concentration respectively, and carrying out ultrasonic dispersion for a third time duration to obtain a uniformly mixed precursor solution;

pouring the precursor solution into a reaction kettle, adding distilled water, thus making a total volume of a reaction solution account for a first preset proportion of a volume of the reaction kettle;

sealing the reaction kettle, transferring the reaction kettle into an air dry oven, and setting a reaction temperature and reaction time to carry out hydrothermal reaction;

after the reaction is completed, naturally cooling the reaction kettle to room temperature, taking out precipitates in the reaction kettle, and respectively centrifugally washing the precipitates with distilled water and absolute ethyl alcohol for a first preset number of times;

carrying out drying in a drying oven at a first temperature for a fourth time duration, carrying out grinding with a mortar, and carrying out calcining in a muffle furnace; and

carrying out grinding again to obtain the bismuth tungstate photocatalyst.

In some embodiments, forming at least one light adjusting layer between the first electrode and the second electrode includes: forming the light adjusting layer between the first electrode and the light emitting layer; or, forming the light adjusting layer between the light emitting layer and the second electrode.

### BRIEF DESCRIPTION OF THE DRAWINGS

FIG. 1 is a first structural schematic diagram of a light emitting device provided by an embodiment of the present disclosure.

FIG. 2 is a second structural diagram of the light emitting device provided by an embodiment of the present disclosure.

FIG. 3 is a third structural diagram of the light emitting device provided by an embodiment of the present disclosure.

FIG. 4 is a fourth structural diagram of the light emitting device provided by an embodiment of the present disclosure.

FIG. 5 is a fifth structural diagram of the light emitting device provided by an embodiment of the present disclosure.

FIG. 6 is a sixth structural diagram of the light emitting device provided by an embodiment of the present disclosure.

FIG. 7 is a seventh structural diagram of the light emitting device provided by an embodiment of the present disclosure.

FIG. 8 is an eighth structural diagram of the light emitting device provided by an embodiment of the present disclosure.

FIG. 9 is a ninth structural diagram of the light emitting device provided by an embodiment of the present disclosure.

FIG. 10 is a structure schematic diagram of an energy level of the light emitting device provided by an embodiment of the present disclosure.

FIG. 11 is a tenth structural diagram of the light emitting device provided by an embodiment of the present disclosure.

FIG. 12 is a flow diagram of manufacturing of the light emitting device provided by an embodiment of the present disclosure.

### DETAILED DESCRIPTION OF THE EMBODIMENTS

In order to make the purpose, the technical solution and the advantages of the embodiment of the present disclosure clearer, the technical solution of the embodiments of the present disclosure is clearly and completely described in combination with the accompanying drawings of the embodiments of the present disclosure. Obviously, the described embodiments are a part of the embodiments of the present disclosure, but not all of the embodiments of the present disclosure. Based on the described embodiments of the present disclosure, all other embodiments obtained by those of ordinary skill in the art without creative labor belong to the scope of protection of the present disclosure.

Unless otherwise defined, the technical or scientific terms used by the present disclosure should be of general meaning understood by those of ordinary skill in the art to which the present disclosure belongs. The “first”, “second”, and similar words used in the present disclosure do not represent any order, number, or importance, but are only used to distinguish different components. Similar words such as “comprise” or “include” mean that elements or objects appearing in front of the word encompass elements or objects listed behind the word and their equivalents, without excluding other elements or objects. Similar words such as “connection” or “link” are not limited to physical or mechanical connection, but may include electrical connection, either direct or indirect. The “upper”, “lower”, “left”, “right” and the like are only used for representing the relative position relation, and when the absolute position of the described object is changed, the relative position relation can also be correspondingly changed.

In order to keep the following description of the embodiments of the present disclosure clear and simple, the present disclosure omits detailed description of known functions and known components.

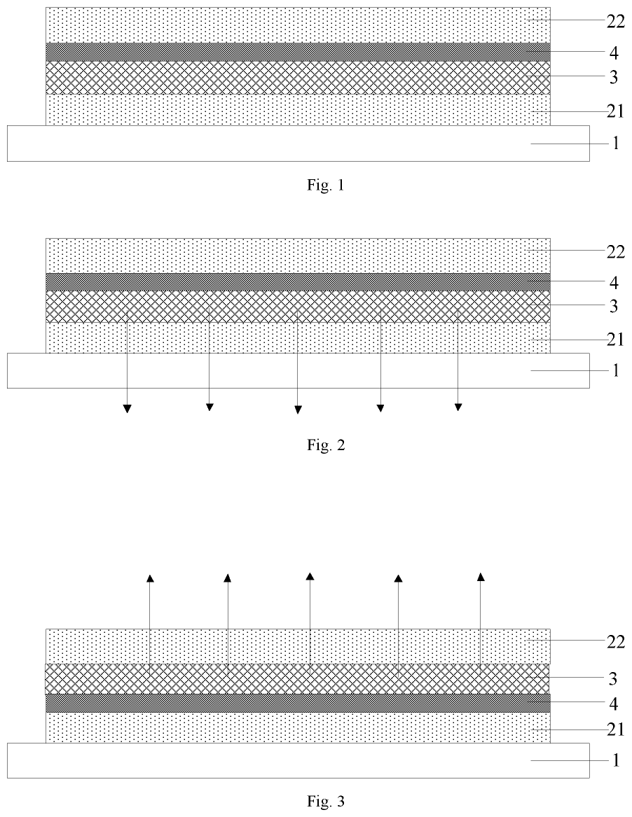

Referring to FIG. 1, an embodiment of the present disclosure provides a light emitting device which includes a base substrate 1, a first electrode 21 located on one side of the base substrate 1, a light emitting layer 3 located on a side, away from the base substrate, of the first electrode 21, and a second electrode 22 located on a side, away from the first electrode 21, of the light emitting layer 3.

At least one light adjusting layer 4 is arranged between the first electrode 21 and the second electrode 22, the light adjusting layer 4 generates carriers when irradiated by light emitted by the light emitting layer 3, and the carriers enter the light emitting layer under the action of an electric field generated by the first electrode 21 and the second electrode 22. In some embodiments, the carriers can be electrons or holes.

In the embodiments of the present disclosure, at least one light adjusting layer is arranged between the first electrode and the second electrode, the light adjusting layer can generate carriers when irradiated by light emitted by the light emitting layer, and the carriers can enter the light emitting layer under the action of the electric field generated by the first electrode and the second electrode; on the one hand, light emitted by the light emitting layer can be utilized to generate the carriers, and the carriers enter the light emitting layer and can participate in the light emitting process again, so that the utilization rate of light emitted by the light emitting layer can be increased, and further the light utilization rate can be increased; and on the other hand, the carriers generated by the light adjusting layer can improve electron hole injection balance by reasonably setting the position of the light adjusting layer, the light emitting efficiency is improved, and the efficiency of the light emitting device is improved.

The embodiments of the present disclosure have the following beneficial effects: in an array base substrate applied by the display panel, a metal oxide thin film transistor takes a metal nanoparticle layer as a protective layer of an active layer, so that the active layer can be protected when a source electrode and a drain electrode are etched, and the poor device caused by corrosion of the active layer is avoided; and meanwhile, the metal nanoparticle layer has good conductivity and good thermal stability, and the requirement for the preparation process of the metal oxide thin film transistor is low, so that the metal oxide thin film transistor with simple process and low cost is prepared.

In some embodiments, the light adjusting layer 4 can be arranged on a reverse path in a light emitting direction, and can generate carriers by using light in a non-light-emitting direction, to avoid influencing the light emitting efficiency of the light emitting device due to absorption of light in the light emitting direction, namely, light emitted by the light emitting layer can propagate in two directions when the light emitting device works, light in one direction is emitted from the direction of a transparent electrode and is used for displaying, and light in the other direction produces light loss due to reflection, refraction and absorption or a waveguide effect generated by a transport layer on the other side in the device. In the embodiment of the present disclosure, the light adjusting layer is arranged on the reverse path in the light emitting direction to absorb non-display light emitted by the light emitting layer so as to excite electron transition, so that carriers are injected into the light emitting layer under the action of the electric field of the light emitting device, and the light utilization rate is increased.

In some embodiments, as shown in FIG. 2, light emitted by the light emitting layer 3 is emitted through the first electrode 21, that is, the light emitting device is of a bottom emission structure, a face, away from the first electrode 21, of the base substrate 1 is a display face, and the light adjusting layer 4 is located between the second electrode 22 and the light emitting layer, where the second electrode 22 includes a reflection electrode.

For another example, as shown in FIG. 3, light emitted by the light emitting layer 3 is emitted through the second electrode 22, the light emitting device is of a top emission structure, and the light adjusting layer 4 is located between the first electrode 21 and the light emitting layer 3.

In some embodiments, the carriers which are generated by the light adjusting layer 4 and enter the light emitting layer 3 can be electrons or holes, and can be determined according to the arrangement position of the light adjusting layer 4 and the electric field generated by the first electrode 21 and the second electrode 22.

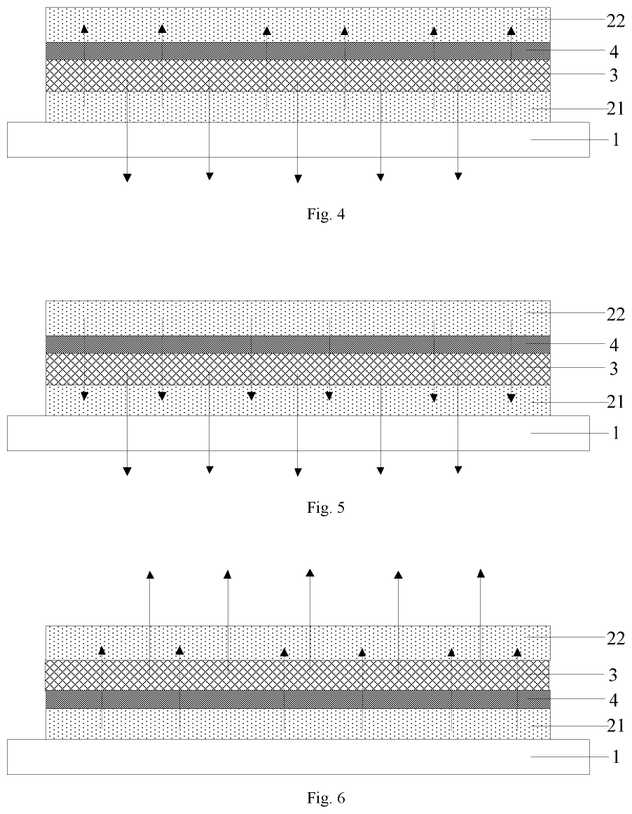

In some embodiments, by taking the bottom emission structure as shown in FIG. 2 as an example, the first electrode 21 can be an anode, the second electrode 22 can be a cathode, a direction of the electric field is from the first electrode 21 to the second electrode 22 (as shown in dotted line arrows in FIG. 4, where solid line arrows in FIG. 4 are the light emitting direction), the light adjusting layer 4 generates electrons when irradiated by light emitted by the light emitting layer 3, and the electrons enter the light adjusting layer 4 under the action of the electric field generated by the first electrode 21 and the second electrode 22, namely, for the light adjusting layer 4 located between the light emitting layer 3 and the second electrode 22, the electrons generated by the light adjusting layer 4 irradiated by light move towards one side of the light emitting layer 3, the generated holes move towards one side of the second electrode 22, and then the electrons finally enter the light emitting layer 3. The arrangement structure of the light adjusting layer 4 can be applied to a light emitting device with the hole-electron injection imbalance condition that the number of holes entering the light emitting layer 3 is greater than the number of electrons. The electrons generated by the light adjusting layer 4 can adjust and control the hole-electron injection imbalance condition that the number of holes reaching the light emitting layer 3 in unit time is greater than the number of the electrons in the bottom emission structure.

In some embodiments, by taking the bottom emission structure as shown in FIG. 2 as an example, the first electrode 21 is a cathode, the second electrode 22 is an anode, and the direction of the electric field is from the second electrode 22 to the first electrode 21 (as shown in dotted line arrows in FIG. 5, where solid line arrows in FIG. 5 are the light emitting direction); and the light adjusting layer 4 generates holes when irradiated by light emitted by the light emitting layer 3, the holes enter the light emitting layer 3 under the action of the electric field generated by the first electrode 21 and the second electrode 22, namely, the light adjusting layer 4 generates electrons when irradiated by light emitted by the light emitting layer 3, and the electrons enter the second electrode 22 under the action of the electric field generated by the first electrode 21 and the second electrode 22, the generated holes move towards one side of the light emitting layer 3, and the holes finally enter the light emitting layer 3. The arrangement structure of the light adjusting layer 4 can be applied to the light emitting device with the hole-electron injection imbalance condition that the number of electrons entering the light emitting layer 3 is greater than the number of holes. Through the holes generated by the light adjusting layer 4, the hole-electron injection imbalance condition that the number of electrons reaching the light emitting layer 3 in unit time is greater than the number of holes in the bottom emission structure can be adjusted and controlled.

In some embodiments, by taking the top emission structure as shown in FIG. 3 as an example, the first electrode 21 is an anode, the second electrode 22 is a cathode, and the direction of the electric field is from the first electrode 21 to the second electrode 22 (as shown in dotted line arrows in FIG. 6, where solid line arrows FIG. 6 are the light emitting direction); and the light adjusting layer 4 generates holes when irradiated by light emitted by the light emitting layer 3, and the holes enter the light emitting layer 3 under the action of the electric field generated by the first electrode 21 and the second electrode 22, namely, for the light adjusting layer 4 located between the light emitting layer 3 and the first electrode 21, electrons generated by the light adjusting layer 4 irradiated by light can move towards one side of the second electrode 22, and the generated holes move towards one side of the light emitting layer 3, and the holes finally enter the light emitting layer 3. The arrangement structure of the light adjusting layer 4 can be applied to the light emitting device with the hole-electron injection imbalance condition that the number of electrons entering the light emitting layer 3 is greater than the number of holes. Through the holes generated by the light adjusting layer 4, the hole-electron injection imbalance condition that the number of electrons reaching the light emitting layer 3 in unit time is greater than the number of the holes in the top emission structure can be adjusted and controlled.

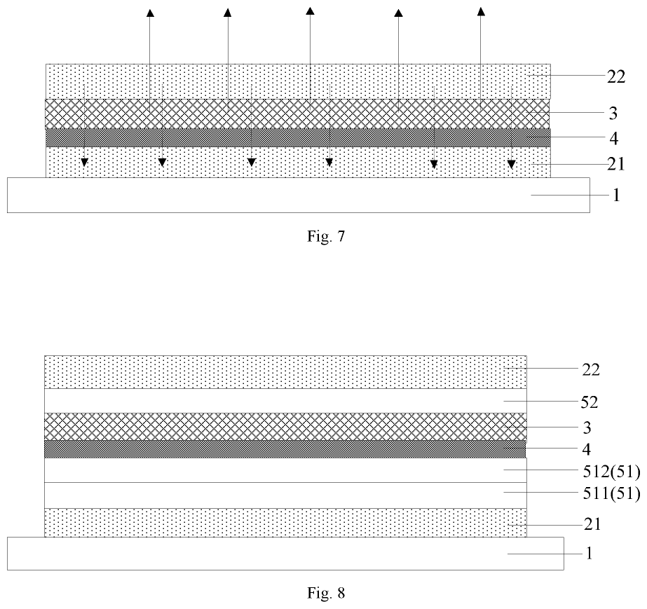

In some embodiments, by taking the top emission structure as shown in FIG. 3 as an example, the first electrode 21 is a cathode, the second electrode 22 is an anode, and the direction of the electric field is from the second electrode 22 to the first electrode 21 (as shown in dotted line arrows in FIG. 7, where solid line arrows in FIG. 7 are the light emitting direction); the light adjusting layer 4 generates electrons when irradiated by light emitted by the light emitting layer 3, and the electrons enter the light emitting layer under the action of the electric field generated by the first electrode 21 and the second electrode 22, namely, for the light adjusting layer 4 located between the light emitting layer 3 and the first electrode 21, the electrons generated by the light adjusting layer 4 irradiated by light move towards one side of the light emitting layer 3, the generated holes move towards one side of the first electrode 21, and the electrons finally enter the light emitting layer 3; and the arrangement structure of the light adjusting layer 4 can be suitable for the light emitting device with the hole-electron injection unbalance that the number of holes entering the light emitting layer 3 is greater than the number of electrons. Through the electrons generated by the light adjusting layer 4, the hole-electron injection imbalance condition that the number of holes reaching the light emitting layer 3 in unit time is greater than the number of electrons in the top emission structure can be adjusted and controlled.

In some embodiments, the condition of hole-electron injection imbalance can be known through experience judgment according to a film layer structure included in the specific light emitting device and the material selected by each film layer, or can be obtained through test according to experiments. For example, the structure of the light emitting device is: an anode, a hole injection layer, a hole transport layer, a quantum dot light emitting layer, an electron transport layer and a cathode which are sequentially located on one side of the base substrate, the light emitting efficiency under the structure of device is tested, an electron injection layer which is more beneficial to electron injection is inserted between the electron transport layer and the cathode layer, if the light emitting efficiency of the device is improved after the electron injection layer is inserted, it is indicated that there is the hole-electron injection imbalance condition that the number of holes reaching the light emitting layer 3 in unit time is greater than the number of electrons. Certainly, during specific implementation, the hole-electron injection imbalance condition of the light emitting device can be tested through other modes.

In some embodiments, the light adjusting layer 4 is located on one side of the light emitting layer 3 and is adjacent to the light emitting layer 3. In the embodiments of the present disclosure, the light adjusting layer 4 is located on one side of the light emitting layer 3 and is adjacent to the light emitting layer 3, so that paths for the carriers generated by the light adjusting layer 4 to move to the light emitting layer can be reduced, and thus more carriers enter the light emitting layer 3.

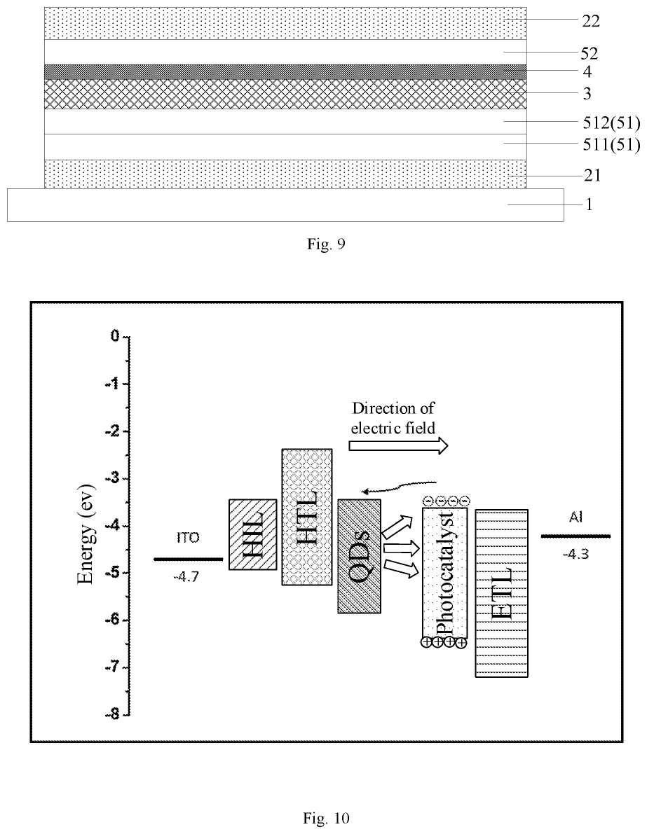

In some embodiments, as shown in FIG. 8 and FIG. 9, the light emitting device further includes: a first functional layer 51 (In some embodiments including a first sub-functional layer 511 and a second sub-functional layer 512) located between the first electrode 21 and the light emitting layer 3, a second functional layer 52 located between the light emitting layer 3 and the second electrode 22; the light adjusting layer 4 is located between the first functional layer 51 and the light emitting layer 3, as shown in FIG. 8; or, the light adjusting layer 4 is located between the second functional layer 52 and the light emitting layer 3. In some embodiments, if the first electrode 21 is an anode, the second electrode 22 is a cathode, the first sub-functional layer 511 can be a hole injection layer, the second sub-functional layer 512 can be a hole transport layer, and the second functional layer 52 can be an electron transport layer.

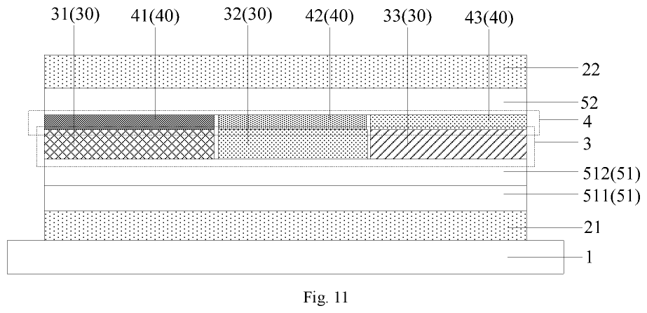

In some embodiments, FIG. 10 shows a schematic diagram of movement of a light adjusting layer of a quantum dot light emitting device under the action of an electric field provided by an embodiment of the present disclosure. In some embodiments, the quantum dot light emitting device includes an anode (the specific material can be indium tin oxide (ITO)), a hole injection layer (HIL), a hole transport layer (HTL), a quantum dot light emitting layer (QDs), a light adjusting layer (the specific material can be a photocatalyst), an electron transport layer (ETL) and a cathode (the specific material can be Al) which are sequentially located on one side of a base substrate, where when the light adjusting layer is irradiated by light emitted by the quantum dot light emitting layer (QDs), electrons and holes are generated, the electrons migrate to the quantum dot light emitting layer (QDs) under the action of an electric field (as shown by an arrow in FIG. 10) from the anode to the cathode, and then the electrons can participate in the electroluminescence process in the quantum dot light emitting layer, the light utilization rate of the light emitting device is increased, so that the light emitting efficiency of the light emitting device is improved, and the electrons and the holes in the light emitting device are balanced.

In some embodiments, a first functional layer 51 (which may In some embodiments include a first sub-functional layer 511 and a second sub-functional layer 512) located between the first electrode 21 and the light emitting layer 3, a second functional layer 52 located between the light emitting layer 3 and the second electrode 22; the light adjusting layer 4 is located between the first functional layer 51 and the first electrode 21; or, the light adjusting layer 4 is located between the second functional layer 52 and the second electrode 22. In some embodiments, if the first electrode 21 is an anode, the second electrode 22 is a cathode, the first sub-functional layer 511 can be a hole injection layer, the second sub-functional layer 512 can be a hole transport layer, and the second functional layer 52 can be an electron transport layer.

In some embodiments, as shown in FIG. 11, the light emitting layer 3 can be provided with a plurality of light emitting parts 30 emitting different light wave bands, the light adjusting layer 4 is provided with adjusting parts 40 corresponding to the different light emitting parts, and band gaps of the different adjusting parts 40 are different. In some embodiments, orthographic projections of the adjusting parts 40 on the base substrate 1 and orthographic projections of the light emitting parts 30 on the base substrate 1 overlap in a one-to-one corresponding manner. In some embodiments, the light emitting layer 3 includes a first light emitting part 31 emitting a first light wave band (e.g., 630-720 nm, red light wave band), a second light emitting part 32 emitting a second light wave band (e.g., 530-630 nm, green light wave band), and a third light emitting part 33 emitting a third light wave band (e.g., 450-530 nm, blue light wave band), where a wavelength range of the first light wave band is larger than a wavelength range of the second light wave band, and the wavelength range of the second light wave band is greater than a wavelength range of the third light wave band, that is, the maximum value in the wavelength range of the second light wave band is smaller than the minimum value in the wavelength range of the first light wave band, and the maximum value in the wavelength range of the third light wave band is smaller than the minimum value in the wavelength range of the second light wave band. The light adjusting layer 4 includes a first adjusting part 41 corresponding to the first light emitting part 31, a second adjusting part 42 corresponding to the second light emitting part 32, and a third adjusting part 43 corresponding to the third light emitting part 33. In some embodiments, the band gaps of the different adjusting parts 40 are different, and the adjusting parts 40 with different band gaps can be correspondingly arranged according to the light emitting parts 30 emitting different light wave bands, so that each adjusting part 40 can absorb light matched with the corresponding light emitting part 30, and further the light utilization rate and the light emitting efficiency corresponding to different pixels are improved.

In some embodiments, the band gaps of the adjusting parts 40 are in negative correlation with the wavelengths of light emitted by the corresponding light emitting parts 30. That is, for example, if the light wave band range of light emitted by the first light emitting part 31 is larger than the light wave band range of light emitted by the second light emitting part 32, the band gap of the first adjusting part 41 corresponding to the first light emitting part 31 is smaller than the band gap of the second adjusting part 42 corresponding to the second light emitting part 32. In some embodiments, the band gap of the first adjusting part is larger than 0 eV and smaller than or equal to 1.97 eV (Eg=hv/λ=1240/630), the band gap of the second adjusting part is larger than 1.97 eV and smaller than or equal to 2.3 eV (Eg=hv/λ=1240/530), and the band gap of the third adjusting part is larger than 2.3 eV and smaller than or equal to 2.8 eV (Eg=hv/λ=1240/450).

In some embodiments, the light adjusting layer can be a uniform and compact film (for example, used in a light emitting device emitting monochromatic light), or an isolated island-shaped deposition (for example, used in a display device emitting multiple light wave bands), or a two-dimensional nanorod or nanowire form.

In some embodiments, a material of the light adjusting layer 4 is a visible light photocatalytic material. In some embodiments, the material of the light adjusting layer includes one or a combination of:

bismuth vanadate;

bismuth phosphate;

bismuth iodate;

bismuth titanate;

a heavy metal ion doped derivative of bismuth vanadate;

a heavy metal ion doped derivative of bismuth phosphate;

a heavy metal ion doped derivative of bismuth iodate;

a heavy metal ion doped derivative of bismuth titanate;

borate;

a precious metal supported derivative of borate;

titanium dioxide; and

an ion-doped derivative of titanium dioxide.

In some embodiments, a dimer or a heteropolymer can be formed by any two of or a combination of more than two of: bismuth vanadate, bismuth phosphate, bismuth iodate, bismuth titanate, the heavy metal ion doped derivative of bismuth vanadate, the heavy metal ion doped derivative of bismuth phosphate, the heavy metal ion doped derivative of bismuth iodate, the heavy metal ion doped derivative of bismuth titanate, borate, the precious metal supported derivative of borate, titanium dioxide and ion-doped derivative of titanium dioxide. In some embodiments, bismuth vanadate, bismuth phosphate, bismuth iodate and bismuth titanate are doped with heavy metal, that is, the band gaps can be adjusted by correspondingly formed heavy metal ion doped derivatives, heavy metal ion doped derivative of bismuth phosphate and heavy metal ion doped derivative of bismuth iodate. In some embodiments, the band gap can be adjusted by the ion-doped derivative of titanium dioxide formed by doping ions in titanium dioxide. In some embodiments, compared with borate, the precious metal supported derivative of borate has higher catalytic activity and can generate more carriers under irradiation of light.

In some embodiments, a thickness of the light adjusting layer 4 ranges from 1 nm to 100 nm. With the increase of the thickness of the film layer of the light adjusting layer 4, more materials capable of absorbing photons emitted by the light emitting layer are excited and more carriers are generated, so that the contribution capability of the carriers is higher, and the thickness can be adjusted and controlled according to the actual electron and hole injection condition of the light emitting device and can be any numerical value from 1 nm to 100 nm, such as 1 nm, 100 nm, etc.

In some embodiments, the light emitting layer 3 can be a quantum dot light emitting layer.

In some embodiments, the light emitting layer 3 can also be an organic light emitting layer.

In order to more clearly understand the arrangement purpose of the light adjusting layer in the light emitting device provided by the embodiment of the present disclosure, the adjustment principle of the light adjusting layer provided by the embodiment of the present disclosure is described as follows.

When the light emitting device works, the light emitting layer emits light to excite the light adjusting layer on one side, so that electrons of the light adjusting layer migrate to a conduction band, and holes are reserved in a valence band. If the light adjusting layer is deposited on one side of the electron transport layer (for example, between the light emitting layer and the electron transport layer), electrons in the conduction band are injected into the quantum dot layer under the action of an electric field, which is adapted to the hole-electron injection imbalance condition that the number of holes reaching the light emitting layer in unit time is greater than the number of electrons; if the light adjusting layer is deposited on one side of the hole transport layer (for example, between the light emitting layer and the hole transport layer), the holes in the valence band are directionally injected into the quantum dot layer under the action of the electric field, which is adapted to the hole-electron injection imbalance condition that the number of electrons reaching the light emitting layer in unit time is greater than the number of holes; and one of the effects of adding the light adjusting layer in the light emitting device is that light which would otherwise be lost in the light emitting device is extracted, and is utilized to excite the photocatalyst to generate electrons and holes which are injected into the quantum dot layer, so that the carrier balance of the device is improved.

In some embodiments, the thickness of the light adjusting layer: the thickness of the light adjusting layer can be any one numerical value from 1 nm to 100 nm, and can be adjusted according to the actual condition of carrier injection in the device. When the thickness of the light adjusting layer is small, the light adjusting layer generates few electrons and holes, and has slight correction effect on carrier imbalance; and when the thickness of the light adjusting layer is very great, the correction effect on carrier imbalance is stronger, but the lighting voltage of the device is increased. Therefore, the thickness of the light adjusting layer is adjusted and controlled according to the actual carrier injection condition of the device. In some embodiments, an absolute value of the difference between the number of electrons reaching the light emitting layer in unit time and the number of holes reaching the light emitting layer in unit time is smaller than or equal to a certain threshold value by adjusting the thickness of the light adjusting layer, so that hole-electron injection balance or basic hole-electron injection balance is achieved, and finally the purpose of improving the light emitting efficiency of the light emitting device is achieved.

Based on the same inventive concept, the embodiments of the present disclosure further provide a display device which includes the light emitting device provided by the embodiment of the present disclosure.

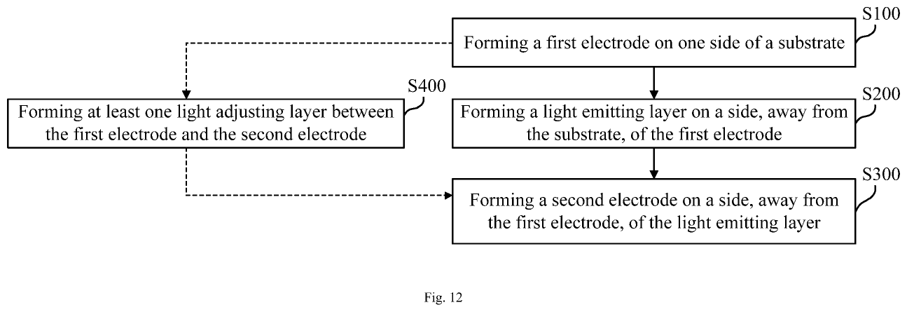

Based on the same inventive concept as shown in FIG. 12, an embodiment of the present disclosure further provides a manufacturing method of the light emitting device provided by the embodiment of the present disclosure, including:

S100, forming a first electrode on one side of a base substrate;

S200, forming a light emitting layer on a side, away from the base substrate, of the first electrode; and

S300, forming a second electrode on a side, away from the first electrode, of the light emitting layer.

After forming the first electrode on one side of the base substrate and before forming the second electrode on a side, away from the first electrode, of the light emitting layer, the manufacturing method further includes:

S400, forming at least one light adjusting layer between the first electrode and the second electrode. In some embodiments, forming at least one light adjusting layer between the first electrode and the second electrode includes:

S410, forming a bismuth tungstate photocatalyst; and

S420, forming the bismuth tungstate photocatalyst between the first electrode and the second electrode through a coating, evaporation, sputtering or printing process.

In some embodiments, the S410 of forming the bismuth tungstate photocatalyst includes:

S4111, weighing Bi(NO₃)₃.5H₂O and Na₂WO₄.2H₂O according to a molar ratio being as a first preset ratio;

S4112, dissolving Na₂WO₄.2H₂O into distilled water, and carrying out magnetic stirring for a first time duration to form a first solution;

S4113, dissolving Bi(NO₃)₃.5H₂O into an HNO₃ solution with a first concentration, and carrying out magnetic stirring for a second time duration to form a second solution;

S4114, while stirring, dropwise adding the first solution into the second solution to form a mixed solution;

S4115, adjusting a pH value of the mixed solution by using an HCl solution with a first concentration and an NaOH solution with a second concentration respectively, and carrying out ultrasonic dispersion for a third time duration to obtain a uniformly mixed precursor solution;

S4116, pouring the precursor solution into a reaction kettle, and adding distilled water, thus making a total volume of a reaction solution account for a first preset proportion of a volume of the reaction kettle;

S4117, sealing the reaction kettle, transferring the sealed reaction kettle into an air dry oven, setting a reaction temperature and reaction time to carry out hydrothermal reaction;

S4118, after the reaction is completed, naturally cooling the reaction kettle to room temperature, taking out precipitates in the reaction kettle, and respectively centrifugally washing the precipitates with distilled water and absolute ethyl alcohol for a first preset number of times;

S4119, carrying out drying in the drying oven at a first temperature for a fourth time duration, carrying out grinding with a mortar, and carrying out calcining in a muffle furnace; and

S4120, carrying out grinding again to obtain the bismuth tungstate photocatalyst.

In some embodiments, the S400 of forming at least one light adjusting layer between the first electrode and the second electrode includes: forming the light adjusting layer between the first electrode and the light emitting layer. In other words, after the first electrode is formed, the light adjusting layer is formed, subsequently, the light emitting layer is formed, and then the second electrode is formed.

In some embodiments, the S400 of forming at least one light adjusting layer between the first electrode and the second electrode includes: forming the light adjusting layer between the light emitting layer and the second electrode. In other words, after the first electrode is formed, the light emitting layer is formed, then the light adjusting layer is formed, and then the second electrode is formed.

The embodiments of the present disclosure have the following beneficial effects: at least one light adjusting layer is arranged between the first electrode and the second electrode, the light adjusting layer can generate the carriers when irradiated by light emitted by the light emitting layer, and the carriers can enter the light emitting layer under the action of the electric field generated by the first electrode and the second electrode; on the one hand, light emitted by the light emitting layer can be utilized to generate the carriers so as to increase the utilization rate of light emitted by the light emitting layer to increase the light utilization rate; and on the other hand, the carriers generated by the light adjusting layer can improve electron-hole injection balance by reasonably setting the position of the light adjusting layer, and the efficiency of the light emitting device is improved.

In order to more clearly understand the manufacturing method of the light emitting device provided by the embodiment of the present disclosure, the material of the light adjusting layer being bismuth tungstate is taken as an example for further detailed description.

(a) The specific preparation process of the bismuth tungstate photocatalyst is as follows: weighing Bi(NO₃)₃.5H₂O and Na₂WO₄.2H₂O according to a molar ratio of 2:1, dissolving Na₂WO₄.2H₂O into a certain amount of distilled water (marked as a solution A, namely a first solution), dissolving Bi(NO₃)₃.5H₂O into a 0.4 mol/L HNO₃ solution (marked as a solution B, namely a second solution), magnetically stirring the two solutions for 30 min to form a colorless transparent solution, dropwise adding the solution A into the solution B under stirring, adjusting the pH value of the mixed solution by using HCl and NaOH solutions with the concentration of 1 mol/L respectively, and carrying out ultrasonic dispersion for 30 min to obtain a uniformly mixed precursor solution; pouring the precursor solution into a stainless steel reaction kettle with a polytetrafluoroethylene lining, adding distilled water to make the total volume of the reaction solution account for 80% of the volume of the hydrothermal reaction kettle, then sealing the reaction kettle, transferring the reaction kettle into the air dry oven, and setting the reaction temperature and reaction time to carry out hydrothermal reaction; and after the reaction is completed, naturally cooling the reaction kettle to room temperature, taking out precipitates in the reaction kettle, respectively centrifugally washing the precipitates with distilled water and absolute ethyl alcohol for three times (the rotating speed of a centrifugal machine is 8000 r/min), drying in a drying oven at 80° C. for 12 hours, carrying out grinding with an agate mortar, carrying out calcining in a muffle furnace, and carrying out grinding again to obtain the Bi₂WO₆ photocatalyst.

(b) A quantum dot light emitting device is prepared as follows: preparing a hole injection layer on a base substrate containing an ITO anode by adopting a coating process, for example, coating hole injection materials such as PEDOT: PSS; then sequentially coating a hole transport layer, quantum dots, a bismuth tungstate photocatalyst and an electron transport layer (such as ZnO nanoparticles); subsequently, carrying out evaporation on a cathode metal thin layer, where the cathode may adopt an Al layer, and the thickness is about 500-1000 nm; and carrying out packaging after evaporation is finished to prepare the quantum dot light emitting device.

Obviously, those skilled in the art can make various modifications and variations on the present disclosure without departing from the spirit and scope of the present disclosure. In this way, if these modifications and variations of the present disclosure belong to the scope of the claims of the present disclosure and their equivalent technologies, the present disclosure is also intended to contain these modifications and variations.

What is claimed is:

1. A light emitting device, comprising:
a base substrate;
a first electrode located on one side of the base substrate;
a light emitting layer located on a side, away from the base substrate, of the first electrode; and
a second electrode located on a side, away from the first electrode, of the light emitting layer;
wherein at least one light adjusting layer is arranged between the first electrode and the second electrode, the at least one light adjusting layer generates carriers when the at least one light adjusting layer is irradiated by light emitted by the light emitting layer, and the carriers enter the light emitting layer under an action of an electric field generated by the first electrode and the second electrode.

2. The light emitting device according to claim 1, wherein the light emitting layer comprises a plurality of light emitting parts emitting different light wave bands, the at least one light adjusting layer comprises adjusting parts corresponding to different light emitting parts, and band gaps of different adjusting parts are different.

3. The light emitting device according to claim 2, wherein a band gap of an adjusting part is in negative correlation with a wavelength of light emitted by a corresponding light emitting part.

4. The light emitting device according to claim 3, wherein the light emitting layer comprises:
a first light emitting part emitting a first light wave band;
a second light emitting part emitting a second light wave band; and
a third light emitting part emitting a third light wave band, wherein
a wavelength range of the first light wave band is greater than a wavelength range of the second light wave band, and the wavelength range of the second light wave band is greater than a wavelength range of the third light wave band; and a light adjusting layer comprises:
a first adjusting part corresponding to the first light emitting part;
a second adjusting part corresponding to the second light emitting part; and
a third adjusting part corresponding to the third light emitting part; wherein
a band gap of the first adjusting part is larger than 0 eV and smaller than or equal to 1.97 eV, a band gap of the second adjusting part is larger than 1.97 eV and smaller than or equal to 2.3 eV, and a band gap of the third adjusting part is larger than 2.3 eV and smaller than or equal to 2.8 eV.

5. The light emitting device according to claim 1, wherein the light emitted by the light emitting layer is emitted through the first electrode, and a light adjusting layer is located between the second electrode and the light emitting layer.

6. The light emitting device according to claim 5, wherein the first electrode is an anode, and the second electrode is a cathode; and the light adjusting layer generates electrons when the light adjusting layer is irradiated by the light emitted by the light emitting layer, and the electrons enter the light emitting layer under the action of the electric field generated by the first electrode and the second electrode; or
the first electrode is a cathode, and the second electrode is an anode; and the light adjusting layer generates holes when the light adjusting layer is irradiated by the light emitted by the light emitting layer, and the holes enter the light emitting layer under the action of the electric field generated by the first electrode and the second electrode.

7. The light emitting device according to claim 1, wherein the light emitted by the light emitting layer is emitted through the second electrode, and a light adjusting layer is located between the first electrode and the light emitting layer.

8. The light emitting device according to claim 7, wherein the first electrode is an anode, and the second electrode is a cathode; and the light adjusting layer generates holes when the light adjusting layer is irradiated by the light emitted by the light emitting layer, and the holes enter the light emitting layer under the action of the electric field generated by the first electrode and the second electrode; or
the first electrode is a cathode, and the second electrode is an anode; and the light adjusting layer generates electrons when the light adjusting layer is irradiated by the light emitted by the light emitting layer, and the electrons enter the light emitting layer under the action of the electric field generated by the first electrode and the second electrode.

9. The light emitting device according to claim 1, wherein the at least one light adjusting layer is located on one side of the light emitting layer and is adjacent to the light emitting layer.

10. The light emitting device according to claim 1, further comprising a first functional layer located between the first electrode and the light emitting layer, and a second functional layer located between the light emitting layer and the second electrode, wherein
the at least one light adjusting layer is located between the first functional layer and the light emitting layer, or the at least one light adjusting layer is located between the second functional layer and the light emitting layer.

11. The light emitting device according to claim 1, further comprising a first functional layer located between the first electrode and the light emitting layer, and a second functional layer located between the light emitting layer and the second electrode, wherein
the at least one light adjusting layer is located between the first functional layer and the first electrode, or the at least one light adjusting layer is located between the second functional layer and the second electrode.

12. The light emitting device according to claim 1, wherein a material of the at least one light adjusting layer is a visible light photocatalytic material.

13. The light emitting device according to claim 12, wherein the material of the at least one light adjusting layer comprises one or a combination of:
bismuth vanadate;
bismuth phosphate;
bismuth iodate;
bismuth titanate;
a heavy metal ion doped derivative of bismuth vanadate;
a heavy metal ion doped derivative of bismuth phosphate;
a heavy metal ion doped derivative of bismuth iodate;
a heavy metal ion doped derivative of bismuth titanate;
borate;
a precious metal supported derivative of borate;
titanium dioxide; and
an ion-doped derivative of titanium dioxide.

14. The light emitting device according to claim 1, wherein a thickness of a light adjusting layer ranges from 1 nm to 100 nm.

15. The light emitting device according to claim 1, wherein the light emitting layer is a quantum dot light emitting layer; or the light emitting layer is an organic light emitting layer.

16. A display device, comprising a light emitting device, wherein the light emitting device comprises:
a base substrate;
a first electrode located on one side of the base substrate;
a light emitting layer located on a side, away from the base substrate, of the first electrode; and
a second electrode located on a side, away from the first electrode, of the light emitting layer;
wherein at least one light adjusting layer is arranged between the first electrode and the second electrode, the at least one light adjusting layer generates carriers when the at least one light adjusting layer is irradiated by light emitted by the light emitting layer, and the carriers enter the light emitting layer under an action of an electric field generated by the first electrode and the second electrode.

17. A manufacturing method of the light emitting device according to claim 1, comprising:
forming the first electrode on one side of the base substrate;
forming the light emitting layer on the side, away from the base substrate, of the first electrode; and
forming the second electrode on the side, away from the first electrode, of the light emitting layer; wherein after the forming the first electrode on one side of the base substrate and before the forming the second electrode on the side, away from the first electrode, of the light emitting layer, the method further comprises:
forming at least one light adjusting layer between the first electrode and the second electrode.

18. The manufacturing method according to claim 17, wherein the forming the at least one light adjusting layer between the first electrode and the second electrode, comprises:
forming a bismuth tungstate photocatalyst; and
forming the bismuth tungstate photocatalyst between the first electrode and the second electrode through a coating, evaporation, sputtering or printing process.

19. The manufacturing method according to claim 17, wherein the forming the bismuth tungstate photocatalyst comprises:
weighing Bi(NO₃)₃.5H₂O and Na₂WO₄.2H₂O according to a molar ratio being as a first preset ratio;
dissolving Na₂WO₄.2H₂O into distilled water, and carrying out magnetic stirring for a first time duration to form a first solution;
dissolving Bi(NO₃)₃.5H₂O into an HNO₃ solution with a first concentration, and carrying out magnetic stirring for a second time duration to form a second solution;
while stirring, dropwise adding the first solution into the second solution to form a mixed solution;
adjusting a pH value of the mixed solution by using an HCl solution with a first concentration and a NaOH solution with a second concentration respectively, and carrying out ultrasonic dispersion for a third time duration to obtain a uniformly mixed precursor solution;
pouring the precursor solution into a reaction kettle, adding distilled water, thus making a total volume of a reaction solution account for a first preset proportion of a volume of the reaction kettle;
sealing the reaction kettle, transferring the reaction kettle into an air dry oven, and setting a reaction temperature and reaction time to carry out hydrothermal reaction;
after the reaction is completed, naturally cooling the reaction kettle to room temperature, taking out precipitates in the reaction kettle, and respectively centrifugally washing the precipitates with distilled water and absolute ethyl alcohol for a first preset number of times;
carrying out drying in a drying oven at a first temperature for a fourth time duration, carrying out grinding with a mortar, and carrying out calcining in a muffle furnace; and
carrying out grinding again to obtain the bismuth tungstate photocatalyst.

20. The manufacturing method according to claim 17, wherein the forming the at least one light adjusting layer between the first electrode and the second electrode comprises: forming the at least one light adjusting layer between the first electrode and the light emitting layer;
or, forming the at least one light adjusting layer between the light emitting layer and the second electrode.
